(19) United States
(12) Patent Application Publication
(10) Pub. No.: US 2024/0088199 A1
(43) Pub. Date: Mar. 14, 2024

(54) TECHNOLOGIES FOR GLASS CORE INDUCTOR

(71) Applicant: Intel Corporation, Santa Clara, CA (US)

(72) Inventors: Brandon Christian Marin, Gilbert, AZ (US); Suddhasattwa Nad, Chandler, AZ (US); Srinivas V. Pietambaram, Chandler, AZ (US); Jeremy D. Ecton, Gilbert, AZ (US); Mohammad Rahman, Gilbert, AZ (US); Gang Duan, Chandler, AZ (US)

(73) Assignee: Intel Corporation, Santa Clara, CA (US)

(21) Appl. No.: 17/943,354

(22) Filed: Sep. 13, 2022

(51) Int. Cl. H01L 49/02; H01F 27/29; H01L 23/498; H01L 25/065; H01L 25/16; H01L 25/18

(52) U.S. Cl. CPC H01L 28/10; H01F 27/292; H01L 23/49827; H01L 25/0657; H01L 25/16; H01L 25/18

(57) ABSTRACT

Techniques for a glass core inductor are disclosed. In the illustrative embodiment, an integrated circuit component includes a glass substrate and a fully-integrated voltage regulator (FIVR). The FIVR includes a glass core inductor that is embedded in the glass substrate. Each inductor turn of the inductor includes two angled through-glass vias and a trace on top of the glass substrate connecting the angled through-glass vias, resulting in an inductor with a cross-section in the shape of a triangle or trapezoid. The inductor may have a relatively large inductance per unit area, requiring less space or allowing for a larger inductance.

### BACKGROUND

Packaged semiconductor dies are ubiquitous in modern electronics. A substrate in a package can have a large number of connections in multiple layers connecting different components. In some cases, a package may include a fully integrated voltage regulator to provide efficient power delivery to semiconductor dies. A voltage regulator may include an inductor, which may take up a relatively large amount of space.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is an isometric view of one embodiment of a system with a glass substrate with an inductor.

FIG. 2 is a top-down view of the system of FIG. 1.

FIG. 3 is a cross-sectional view of the system of FIG. 1.

FIG. 4 is a side view of the system of FIG. 1.

FIG. 5 is a side view of the system of FIG. 1.

FIG. 6 is a simplified flow diagram of at least one embodiment of a method for manufacturing a system with a glass substrate with an inductor.

FIG. 7 is a cross-sectional view of using a laser to prepare a glass substrate for etching.

FIG. 8 is a cross-sectional view of a glass substrate with angled cavities.

FIG. 9 is a cross-sectional view of a glass substrate with angled conductors extending from the top surface of a glass substrate to the bottom surface.

FIG. 10 is a cross-sectional view of a glass substrate with traces patterned on the top and bottom surfaces.

FIG. 11 is a top view of a wafer and dies that may be included in a microelectronic assembly, in accordance with any of the embodiments disclosed herein.

FIG. 12 is a cross-sectional side view of an integrated circuit device that may be included in a microelectronic assembly, in accordance with any of the embodiments disclosed herein.

FIGS. 13A-13D are perspective views of example planar, gate-all-around, and stacked gate-all-around transistors.

FIG. 14 is a cross-sectional side view of an integrated circuit device assembly that may include a microelectronic assembly, in accordance with any of the embodiments disclosed herein.

FIG. 15 is a block diagram of an example electrical device that may include a microelectronic assembly, in accordance with any of the embodiments disclosed herein.

### DETAILED DESCRIPTION OF THE DRAWINGS

In the illustrative embodiment disclosed herein, a system includes a glass substrate as part of an integrated circuit component, such as a processor. The illustrative integrated circuit component includes a fully-integrated voltage regulator (FIVR). The glass substrate includes an inductor that forms part of the FIVR. The inductor includes conductors extending from the top surface of the glass substrate to the bottom surface at an angle. Adjacent turns of the inductor are connected by a conductor on the top surface of the glass substrate. The profile of each turn of the inductor is roughly triangular, leading to a compact inductor with a relatively high inductance per unit area.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Optical components such as fibers or waveguides may be “connected” if the gap between them is small enough that light can be transferred from one fiber or waveguide to another fiber or waveguide without any intervening optical elements, such as a lens or mirror. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

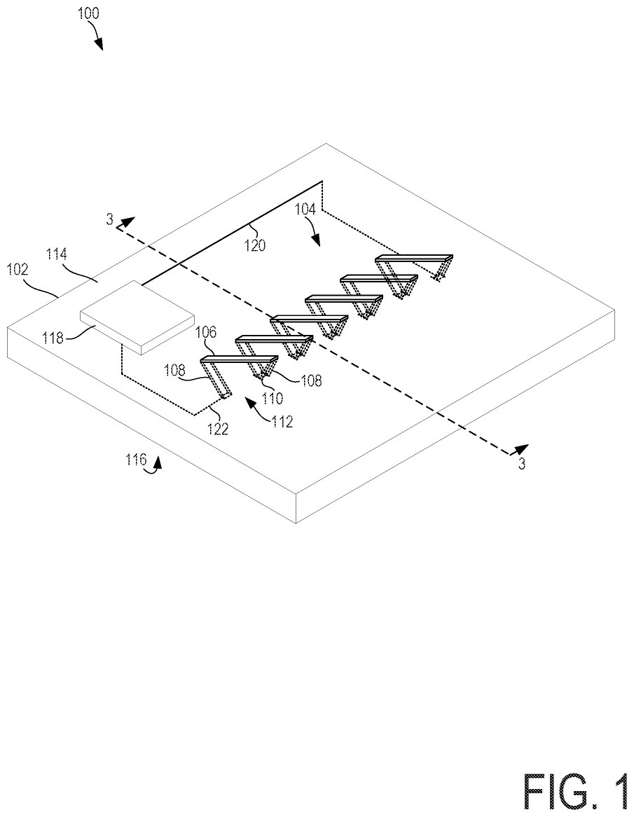

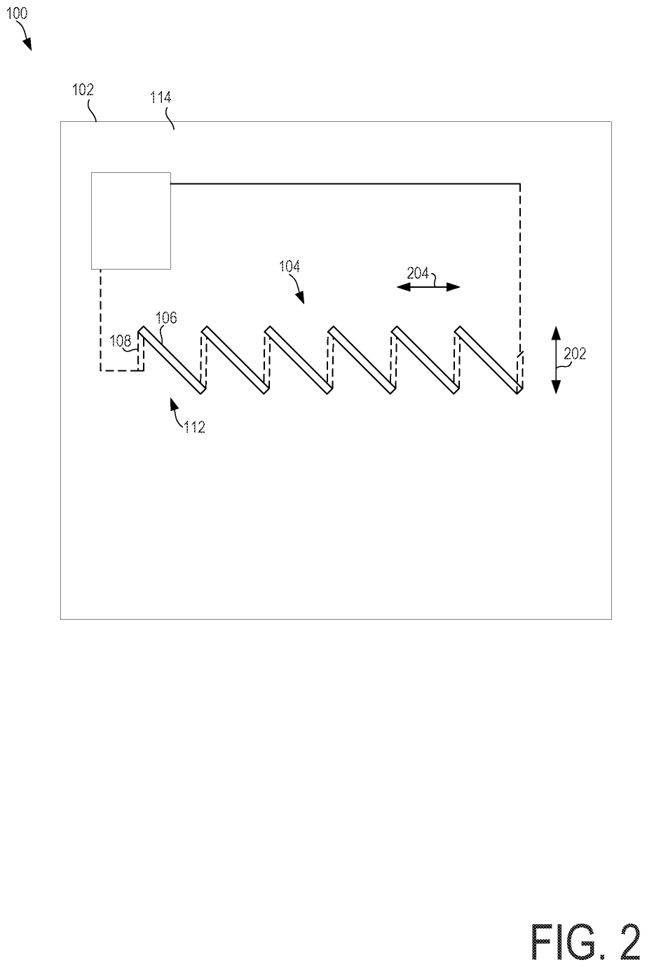

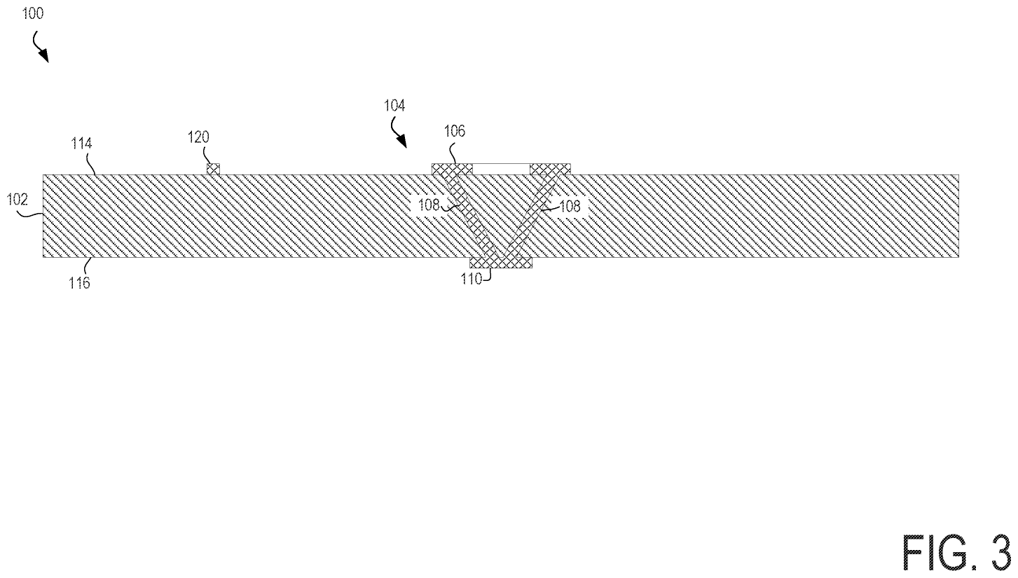

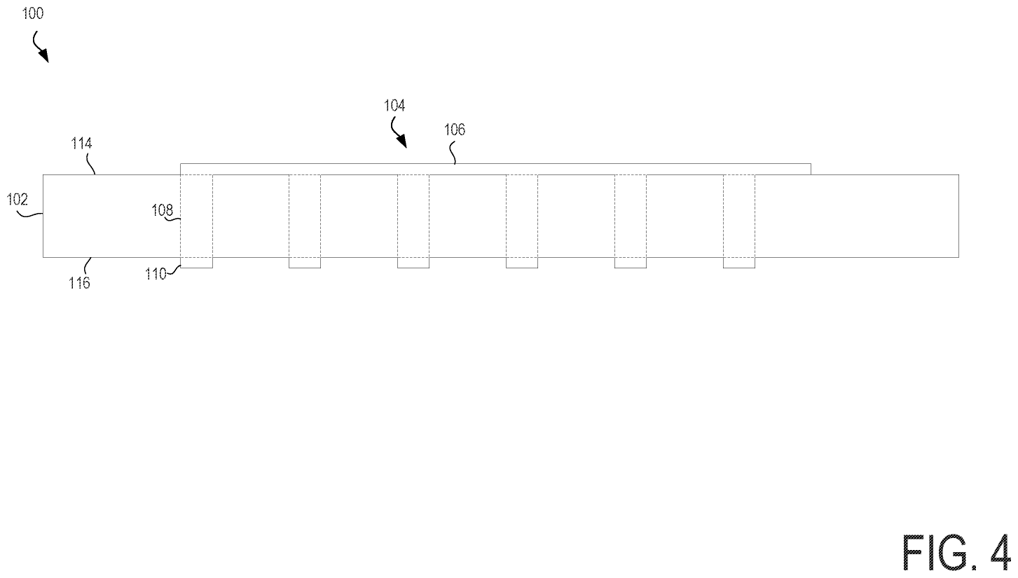

Referring now to FIGS. 1-4, in one embodiment, a system 100 includes a glass substrate 102. FIG. 1 shows an isometric view of the system 100, FIG. 2 shows a top-down view of the system 100, FIG. 3 shows a cross-sectional view of the system 100 taken at the line 3 shown in FIG. 1, and FIG. 4 shows a side view of the system 100. The illustrative system 100 includes an inductor 104 defined in the glass substrate 102. The inductor 104 includes several inductor turns 112. In the illustrative embodiment, each inductor turn 112 includes two angled through-glass vias 108 filled with a conductor that extend from the top surface 114 of the glass substrate 102 to the bottom surface 116. As used herein, an angled via refers to a via oriented at an angle of at least 20° relative to a line normal to the top surface 114 of the glass substrate 102. It should be appreciated that “top surface,” “bottom surface,” etc., are arbitrary orientations and do not require a particular orientation of the glass substrate 102 or other component during manufacture or use.

A conductive trace 106 on the top surface 114 connects the angled through-glass vias 108 of the inductor turn 112. In the illustrative embodiment, the inductor turn 112 includes a pad 110 on the bottom surface 116 of the glass substrate 102 that connects the inductor turn 112 to the next inductor turn 112. The two through-glass vias 108 of the inductor turn 112 are angled in opposite directions, such that a cross-sectional profile of the inductor 104 has approximately a triangular (or trapezoidal) shape, as shown in FIG. 3. It should be appreciated that the inductor 104 has a glass core, rather than a magnetic core. Additionally, it should be appreciated that additional inductor turns 112 can be added to the inductor 104 without requiring additional layers, allowing for flexibility in the number of inductor turns 112 in the inductor 104.

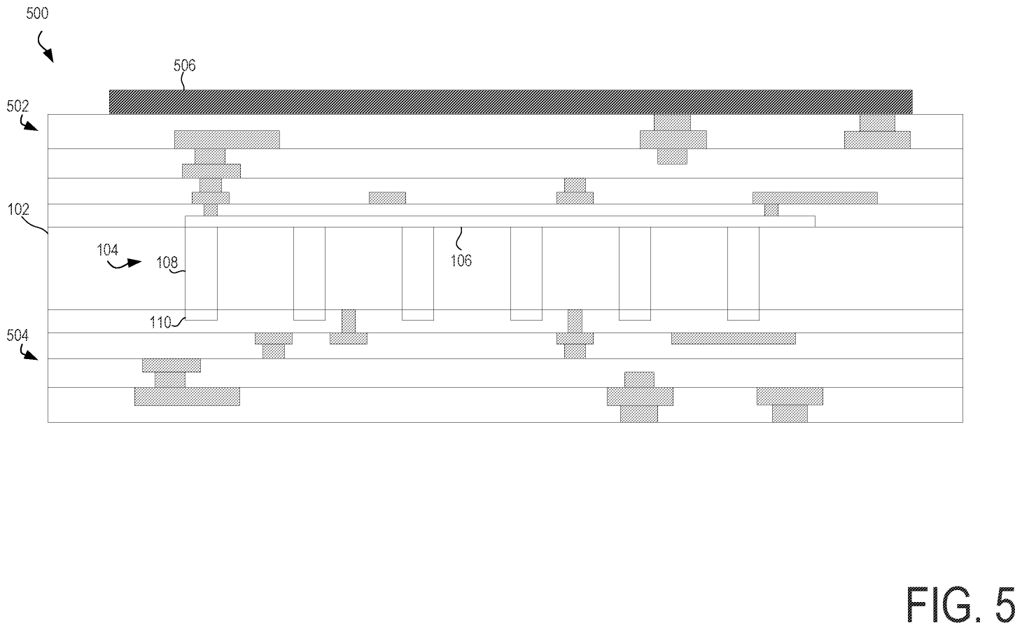

In use, the inductor 104 is connected to other components of a fully-integrated voltage regulator (FIVR) 118 through interconnects 120, 122, such as the FIVR 118 shown in FIG. 1. The FIVR 118 may include components such as capacitors transistors, resistors, etc. Some or all of the components of the FIVR 118 may be adjacent the glass substrate 102, may be located on build-up layers 502, 504 on the glass substrate 102, or may be located on a semiconductor die 506 (see FIG. 5). A relatively large amount of current, such as 1-10 amps, may be able to flow through the inductor 104, facilitating the FIVR 118 in regulating voltage to components of the system 500 in FIG. 5, such as the die 506.

The glass substrate 102 can be any suitable substrate, such as borosilicate glass, fused silica, etc. In some embodiments, a non-glass substrate 102 may be used instead of the glass substrate 102, such as quartz or silicon.

In the illustrative embodiment, the through-glass vias 108 are filled with copper, and the conductive traces 106 and the conductive pads 110 are copper. In other embodiments, a different conductive material may be used, such as aluminum, gold, silver, polysilicon, etc.

The various dimensions of the system 100 may depend on the requirements of a particular application, such as inductance density, maximum current density, etc. In the illustrative embodiment, the thickness of the glass substrate 102 may be, e.g., 100-800 micrometers. The diameter of the through-glass vias 108 may be, e.g., 20-50 micrometers. The width of the traces 106 and pads 110 may be, e.g., 5-100 micrometers. The thickness of the traces 106 and pads 110 may be, e.g., 5-50 micrometers. The width 202 of the inductor 104 may be, e.g., 80-300 micrometers. The pitch 204 between inductor turns 112 may be, e.g., 80-300 micrometers. The inductor 104 may have any suitable number of inductor turns 112, such as 5-20 inductor turns 112. The through-glass vias 108 may be angled at any suitable angle relative to a line normal to the top surface 114 of the glass substrate 102, such as 20-70°.

The inductance density depends on the particular dimensions of the inductor 104. For example, in one embodiment, the through-glass via pitch 204 and width 202 of the inductor 104 are 100 micrometers, the diameter of the through-glass vias 108 are 30 micrometers, the angle of the through-glass vias 108 relative to a line normal to the top surface 114 of the glass substrate 102 are 30°, the thickness of the traces 106 and pads 110 are 20 micrometers, and the thickness of the glass substrate 102 is 300 micrometers. In such an embodiment, the inductance density is about 39 nanohenries per square millimeter. If such an embodiment had five inductor turns 112, the total inductance would be about 1.95 nanohenries.

In another embodiment, the through-glass via pitch 204 and width 202 of the inductor 104 are 100 micrometers, the diameter of the through-glass vias 108 are 50 micrometers, the angle of the through-glass vias 108 relative to a line normal to the top surface 114 of the glass substrate 102 are 30°, the thickness of the traces 106 and pads 110 are 20 micrometers, and the thickness of the glass substrate 102 is 300 micrometers. In such an embodiment, the inductance density is about 34 nanohenries per square millimeter.

It should be appreciated that the embodiments shown in FIGS. 1-4 are merely one possible embodiment of the inductor 104 and that additional variations are envisioned. For example, in some embodiments, the inductor may not include pads 110 for some or all of the inductor turns 112, and the through-glass vias 108 may be directly connected, such as at the bottom surface 116 of the glass substrate 102. In the illustrative embodiment, all of the through-glass vias 108 have the same angle relative to a line normal to the top surface 114 of the glass substrate 102. In other embodiments, different through-glass vias 108 may have different angles. It should be appreciated that the inductor 104 does not need to start or end with any particular part of an inductor turn 112. For example, the inductor 104 may begin or end with either angled through-glass via 108, the pad 110, or the trace 106.

In some embodiments, the glass substrate 102 may include more than one inductor 104. Additionally or alternatively, the glass substrate 102 may include an inductor 104 with inductor turns 112 oriented in a configuration other than the straight line shown in FIGS. 1-4. For example, an inductor 104 may be embodied as several inductor turns 112 extending in a first direction parallel to the top surface 114 and several inductor turns 112 extending in a second direction opposite the first direction in an out-and-back configuration. In another embodiment, the inductor turns 112 may be oriented in a circle, creating a toroid-shaped inductor 104.

Referring now to FIG. 5, the glass substrate with the inductor 104 forms part of an integrated circuit component 500. The integrated circuit component 500 may include build-up layers 502 and/or 504 that are built up on the glass substrate 102 using any suitable technique, such as semi-additive processing. The build-up layers 502 and/or 504 may include device layers and/or interconnect layers. The build-up layers 502 may include interconnect structure, vias, pads, traces, active components such as transistors, some or all of the components of the FIVR 118, and/or the like. In the illustrative embodiment, one or more semiconductor dies 506 are adjacent a top surface of the top build-up layer 502. The semiconductor die 506 may be, e.g., a processor die, a memory die, a network die, a field-programmable gate array (FPGA) die, an application-specific integrated circuit (ASIC) die, etc. The total thickness of the glass substrate 102 and the build-up layers 502, 504 may be any suitable thickness, such as 300-2,000 micrometers. The semiconductor die 506 may have any suitable thickness, such as 100-1,000 micrometers.

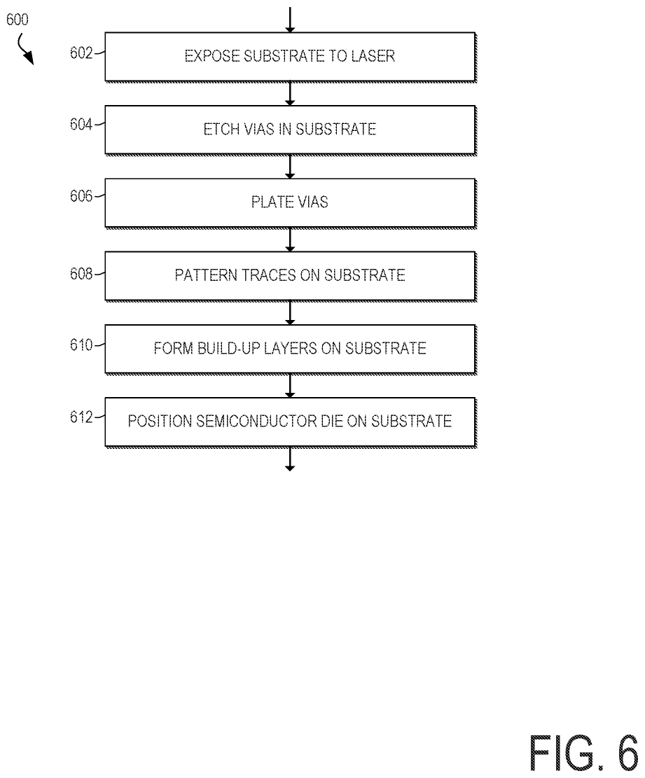

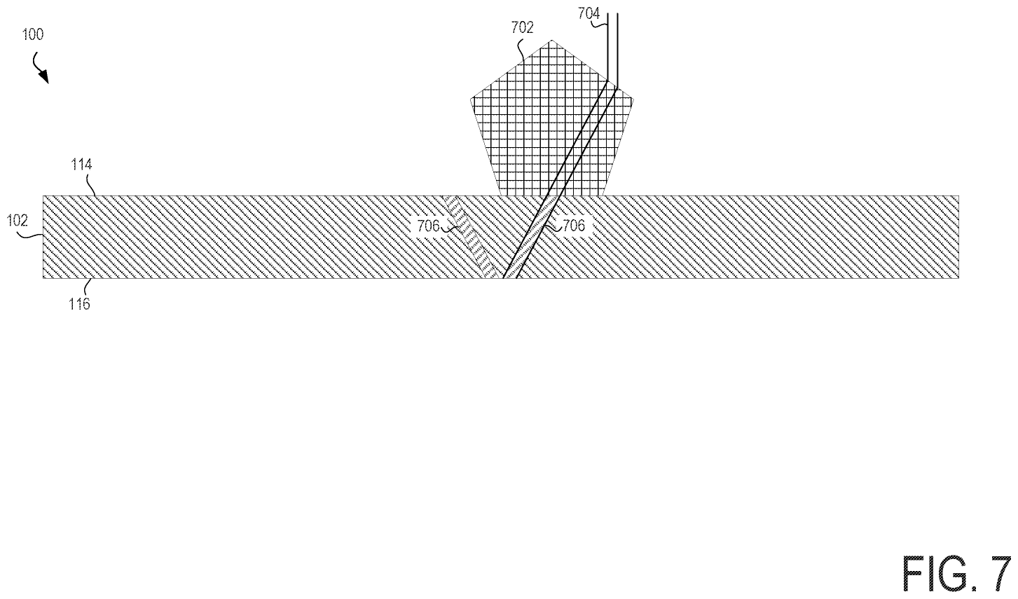

Referring now to FIG. 6, in one embodiment, a flowchart for a method 600 for creating the system 100 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, causes the machine to perform some or all of the steps of the method 600. The method 600 may use any suitable set of techniques that are used in integrated circuit or semiconductor processing, such as chemical vapor deposition, atomic layer deposition, physical layer deposition, molecular beam epitaxy, layer transfer, photolithography, ion implantation, dry etching, wet etching, thermal treatments, flip chip, layer transfer, magnetron sputter deposition, pulsed laser deposition, laser-induced deep etching (LIDE), selective laser etching, etc. It should be appreciated that the method 600 is merely one embodiment of a method to create the system 100, and other methods may be used to create the system 100. In some embodiments, steps of the method 600 may be performed in a different order than that shown in the flowchart. FIGS. 7-10 show cross-sectional views of the glass substrate 102 at various steps of the method 600.

The method 600 beings in block 602, in which a glass substrate 102 is exposed to a laser beam 704 as part of a laser-induced deep etching (LIDE) process, as shown in FIG. 7. In the illustrative embodiment, the laser beam 704 is directed at the glass substrate 102 in a direction that is normal to the top surface 114 of the glass substrate 102. A prism 702 placed adjacent or near the top surface 114 deflects the laser beam 704 such that it is at an angle relative to a line normal to the top surface 114 of the glass substrate 102. In other embodiments, the laser beam 704 may be angled relative to a line normal to the top surface 114 of the glass substrate without using a prism 702, such as by rotating a source of the laser beam 704. As the glass substrate is exposed to the laser beam 704, the laser beam 704 alters the structure of the glass substrate 102, forming one or more angled exposed regions 706 that are pre-cursors to the angled through-glass vias 108.

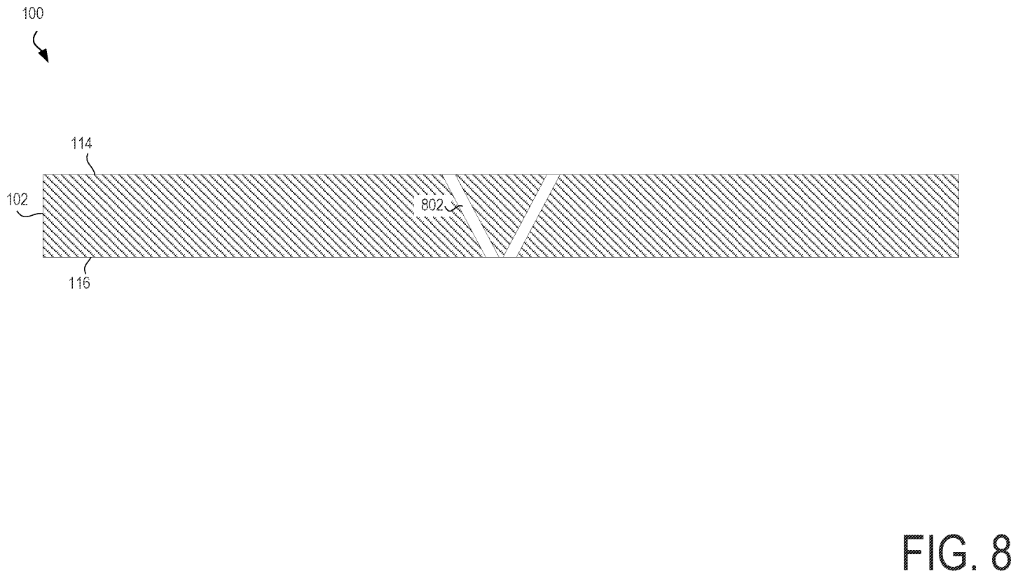

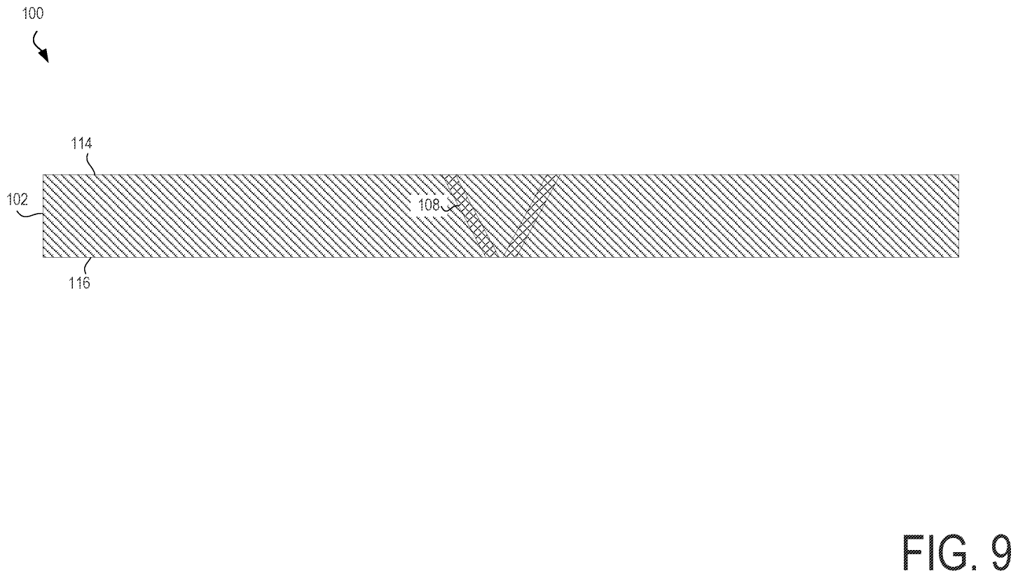

In block 604, the angled exposed regions 706 are etched away to create angled through-glass vias 802 that are not yet filled with conductive material, completing the LIDE process, as shown in FIG. 8. The angled exposed regions 706 may be etched in any suitable manner, such as by using wet chemical etching with, e.g., hydrofluoric acid. In block 606, the angled through-glass vias 802 are filled with a conductor such as copper to form the conductive angled through-glass vias 108, as shown in FIG. 9.

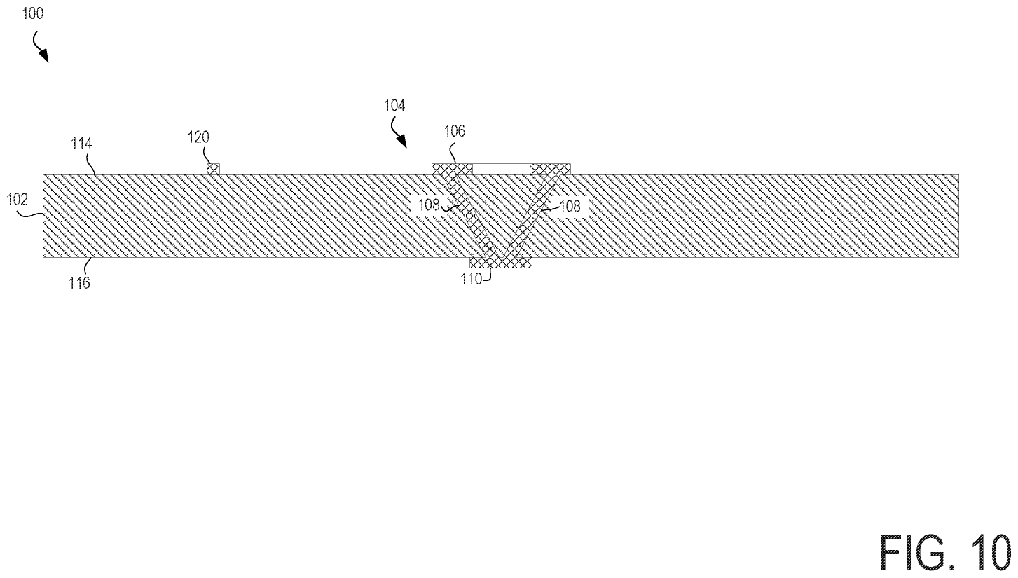

In block 608, traces 106 and pads 110 are patterned on the glass substrate 102, as shown in FIG. 10. In block 610, build-up layers 502, 504 are added on top and on bottom of the glass substrate 102. As part of adding the build-up layers 502, 504, in some embodiments, some or all of the components of the FIVR 118 may be connected to the inductor 104. In block 612, one or more semiconductor dies 506 are positioned on top of the build-up layer 502.

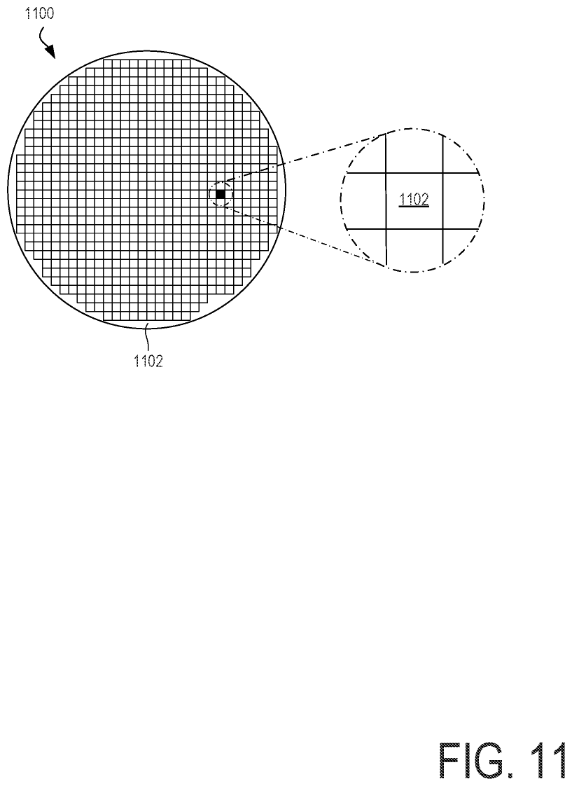

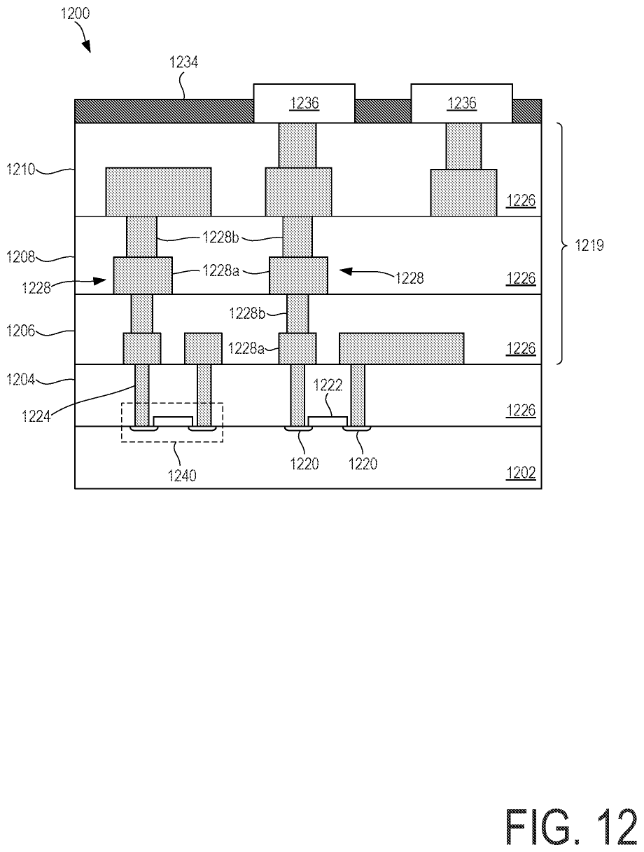

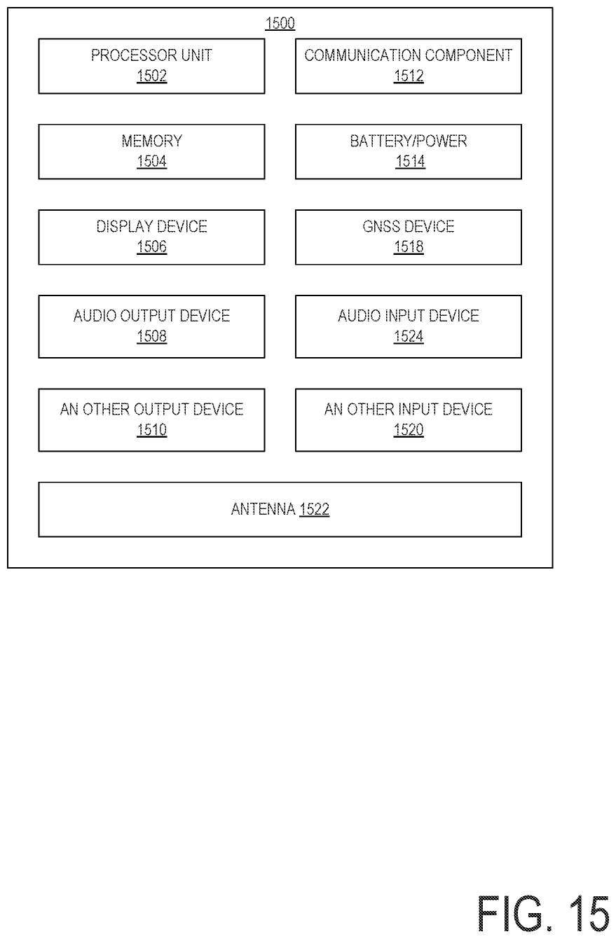

FIG. 11 is a top view of a wafer 1100 and dies 1102 that may be included in any of the integrated circuit components 500 disclosed herein (e.g., as any suitable ones of the dies 506). The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may be any of the dies 506 disclosed herein. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1502 of FIG. 15) or other logic that is configured to store information in the memory devices or execute instructions stored in the memory array. Various ones of the integrated circuit components 500 disclosed herein may be manufactured using a die-to-wafer assembly technique in which some dies 506 are attached to a wafer 1100 that include others of the dies 506, and the wafer 1100 is subsequently singulated.

FIG. 12 is a cross-sectional side view of an integrated circuit device 1200 that may be included in or be embodied as any of the integrated circuit components 500 disclosed herein. One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

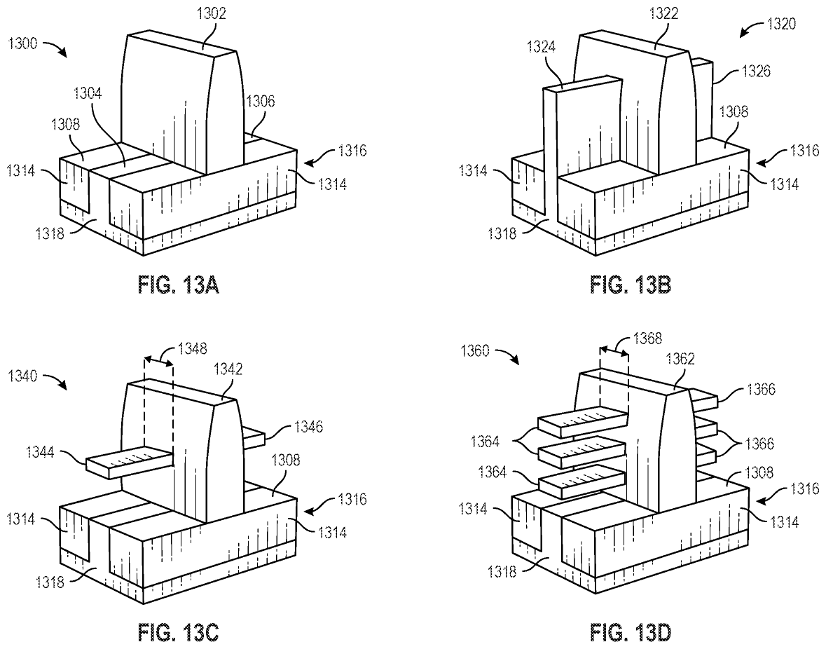

FIGS. 13A-13D are simplified perspective views of example planar, FinFET, gate-all-around, and stacked gate-all-around transistors. The transistors illustrated in FIGS. 13A-13D are formed on a substrate 1316 having a surface 1308. Isolation regions 1314 separate the source and drain regions of the transistors from other transistors and from a bulk region 1318 of the substrate 1316.

FIG. 13A is a perspective view of an example planar transistor 1300 comprising a gate 1302 that controls current flow between a source region 1304 and a drain region 1306. The transistor 1300 is planar in that the source region 1304 and the drain region 1306 are planar with respect to the substrate surface 1308.

FIG. 13B is a perspective view of an example FinFET transistor 1320 comprising a gate 1322 that controls current flow between a source region 1324 and a drain region 1326. The transistor 1320 is non-planar in that the source region 1324 and the drain region 1326 comprise “fins” that extend upwards from the substrate surface 1328. As the gate 1322 encompasses three sides of the semiconductor fin that extends from the source region 1324 to the drain region 1326, the transistor 1320 can be considered a tri-gate transistor. FIG. 13B illustrates one S/D fin extending through the gate 1322, but multiple S/D fins can extend through the gate of a FinFET transistor.

FIG. 13C is a perspective view of a gate-all-around (GAA) transistor 1340 comprising a gate 1342 that controls current flow between a source region 1344 and a drain region 1346. The transistor 1340 is non-planar in that the source region 1344 and the drain region 1346 are elevated from the substrate surface 1328.

FIG. 13D is a perspective view of a GAA transistor 1360 comprising a gate 1362 that controls current flow between multiple elevated source regions 1364 and multiple elevated drain regions 1366. The transistor 1360 is a stacked GAA transistor as the gate controls the flow of current between multiple elevated S/D regions stacked on top of each other. The transistors 1340 and 1360 are considered gate-all-around transistors as the gates encompass all sides of the semiconductor portions that extends from the source regions to the drain regions. The transistors 1340 and 1360 can alternatively be referred to as nanowire, nanosheet, or nanoribbon transistors depending on the width (e.g., widths 1348 and 1368 of transistors 1340 and 1360, respectively) of the semiconductor portions extending through the gate.

Returning to FIG. 12, a transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

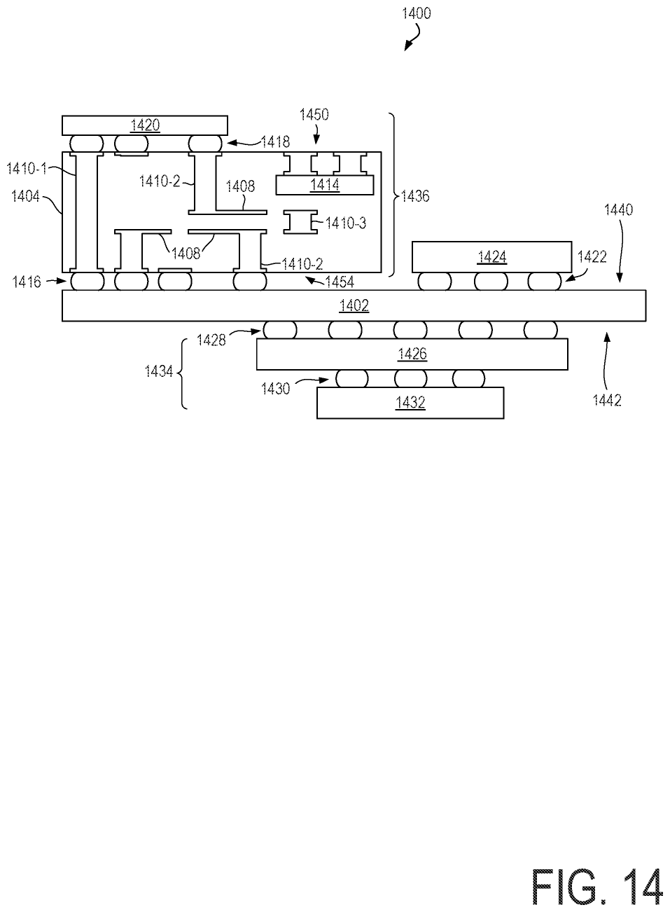

FIG. 14 is a cross-sectional side view of an integrated circuit device assembly 1400 that may include or be included in any of the integrated circuit components 500 disclosed herein. In some embodiments, the integrated circuit device assembly 1400 may be an integrated circuit components 500. The integrated circuit device assembly 1400 includes a number of components disposed on a circuit board 1402 (which may be a motherboard, system board, mainboard, etc.). The integrated circuit device assembly 1400 includes components disposed on a first face 1440 of the circuit board 1402 and an opposing second face 1442 of the circuit board 1402; generally, components may be disposed on one or both faces 1440 and 1442. Any of the integrated circuit components discussed below with reference to the integrated circuit device assembly 1400 may take the form of any suitable ones of the embodiments of the integrated circuit components 500 disclosed herein.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The integrated circuit device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpacked integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1420, a single monolithic integrated circuit die comprises solder bumps attached to contacts on the die. The solder bumps allow the die to be directly attached to the interposer 1404. The integrated circuit component 1420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1420 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art. In embodiments where the interposer is a non-printed circuit board

The integrated circuit device assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit device assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the integrated circuit components 500 disclosed herein. For example, any suitable ones of the components of the electrical device 1500 may include one or more of the integrated circuit device assemblies 1400, integrated circuit components 1420, integrated circuit devices 1200, or integrated circuit dies 1102 disclosed herein, and may be arranged in any of the integrated circuit components 500 disclosed herein. A number of components are illustrated in FIG. 15 as included in the electrical device 1500, but any one or more of these components may be omitted or duplicated, as suitable for the application. In some embodiments, some or all of the components included in the electrical device 1500 may be attached to one or more motherboards mainboards, or system boards. In some embodiments, one or more of these components are fabricated onto a single system-on-a-chip (SoC) die.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1500 can comprise one or more processor units 1502 that are heterogeneous or asymmetric to another processor unit 1502 in the electrical device 1500. There can be a variety of differences between the processing units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include an other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include an other input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a glass substrate comprising an inductor, the inductor comprising a plurality of angled through-glass vias, wherein individual angled through-glass vias of the plurality of angled through-glass vias extend from a top surface of the glass substrate to a bottom surface of the glass substrate; and a plurality of traces on the top surface of the glass substrate, wherein individual traces of the plurality of traces extend from one of the plurality of angled through-glass vias to another of the plurality of angled through-glass vias.

Example 2 includes the subject matter of Example 1, and wherein the apparatus comprises an integrated circuit component, wherein the integrated circuit component comprises the glass substrate, wherein the integrated circuit component comprises a fully-integrated voltage regulator (FIVR), wherein the FIVR comprises the inductor.

Example 3 includes the subject matter of any of Examples 1 and 2, and wherein the plurality of angled through-glass vias have a pitch between 80 and 300 micrometers.

Example 4 includes the subject matter of any of Examples 1-3, and wherein the inductor has inductance density greater than 20 nanohenries per square millimeter.

Example 5 includes the subject matter of any of Examples 1-4, and wherein the inductor has inductance greater than one nanohenry.

Example 6 includes the subject matter of any of Examples 1-5, and further including a plurality of pads on the bottom surface of the glass substrate, wherein individual pads of the plurality of pads connect two of the angled through-glass vias of the plurality of angled through-glass vias.

Example 7 includes the subject matter of any of Examples 1-6, and further including a first plurality of build-up layers adjacent the top surface of the glass substrate; a second plurality of build-up layers adjacent the bottom surface of the glass substrate; and a semiconductor die adjacent the first plurality of build-up layers.

Example 8 includes the subject matter of any of Examples 1-7, and wherein the semiconductor die is a processor die.

Example 9 includes the subject matter of any of Examples 1-8, and wherein the semiconductor die is a memory die.

Example 10 includes the subject matter of any of Examples 1-9, and wherein the glass substrate comprises a second inductor, the second inductor comprising a second plurality of angled through-glass vias, wherein individual angled through-glass vias of the second plurality of angled through-glass vias extend from the top surface of the glass substrate to the bottom surface of the glass substrate; and a second plurality of traces on the top surface of the glass substrate, wherein individual traces of the second plurality of traces extend from one of the second plurality of angled through-glass vias to another of the second plurality of angled through-glass vias.

Example 11 includes an apparatus comprising a glass substrate comprising an inductor, the inductor comprising a plurality of inductor turns, wherein individual inductor turns of the plurality of inductor turns comprise a first conductor extending from a top surface of the glass substrate to a bottom surface of the glass substrate, wherein the first conductor is angled at least ten degrees relative to a line normal to the top surface of the glass substrate; a second conductor extending from the top surface of the glass substrate to the bottom surface of the glass substrate, wherein the second conductor is angled at least ten degrees relative to the line normal to the top surface of the glass substrate, wherein the second conductor is electrically coupled to the first conductor; and a third conductor extending along the top surface of the glass substrate, wherein the third conductor is electrically coupled to the second conductor and an adjacent inductor turn of the inductor.

Example 12 includes the subject matter of Example 11, and wherein the apparatus comprises an integrated circuit component, wherein the integrated circuit component comprises the glass substrate, wherein the integrated circuit component comprises a fully-integrated voltage regulator (FIVR), wherein the FIVR comprises the inductor.

Example 13 includes the subject matter of any of Examples 11 and 12, and wherein a distance between the first conductor and the second conductor of individual inductor turns of the plurality of inductor turns at the top surface is between 80 and 300 micrometers.

Example 14 includes the subject matter of any of Examples 11-13, and wherein the inductor has inductance density greater than 20 nanohenries per square millimeter.

Example 15 includes the subject matter of any of Examples 11-14, and wherein the inductor has inductance greater than one nanohenry.

Example 16 includes the subject matter of any of Examples 11-15, and further including a plurality of pads on the bottom surface of the glass substrate, wherein individual pads of the plurality of pads connect the first conductor to the second conductor of individual inductor turns of the plurality of inductor turns.

Example 17 includes the subject matter of any of Examples 11-16, and further including a first plurality of build-up layers adjacent the top surface of the glass substrate; a second plurality of build-up layers adjacent the bottom surface of the glass substrate; and a semiconductor die adjacent the first plurality of build-up layers.

Example 18 includes the subject matter of any of Examples 11-17, and wherein the semiconductor die is a processor die.

Example 19 includes the subject matter of any of Examples 11-18, and wherein the semiconductor die is a memory die.

Example 20 includes the subject matter of any of Examples 11-19, and wherein the glass substrate comprises a second inductor, the second inductor comprising a second plurality of inductor turns, wherein individual inductor turns of the second plurality of inductor turns comprise a first conductor extending from the top surface of the glass substrate to the bottom surface of the glass substrate, wherein the first conductor is angled at least ten degrees relative to a line normal to the top surface of the glass substrate; a second conductor extending from the top surface of the glass substrate to the bottom surface of the glass substrate, wherein the second conductor is angled at least ten degrees relative to the line normal to the top surface of the glass substrate, wherein the second conductor is electrically coupled to the first conductor; and a third conductor extending along the top surface of the glass substrate, wherein the third conductor is electrically coupled to the second conductor and an adjacent inductor turn of the second inductor.

Example 21 includes an apparatus comprising a glass substrate comprising means for a glass-core inductor with an inductance density greater than 20 nanohenries per square millimeter; a first plurality of build-up layers adjacent a top surface of the glass substrate; and a second plurality of build-up layers adjacent a bottom surface of the glass substrate.

Example 22 includes the subject matter of Example 21, and wherein the apparatus comprises an integrated circuit component, wherein the integrated circuit component comprises the glass substrate, wherein the integrated circuit component comprises a fully-integrated voltage regulator (FIVR), wherein the FIVR comprises the glass-core inductor.

Example 23 includes the subject matter of any of Examples 21 and 22, and wherein the glass-core inductor comprises a plurality of inductor turns, wherein the plurality of inductor turns have a pitch between 80 and 300 micrometers.

Example 24 includes the subject matter of any of Examples 21-23, and wherein the glass-core inductor has inductance density greater than 20 nanohenries per square millimeter.

Example 25 includes the subject matter of any of Examples 21-24, and wherein the glass-core inductor has inductance greater than one nanohenry.

Example 26 includes the subject matter of any of Examples 21-25, and further including a semiconductor die adjacent the first plurality of build-up layers.

Example 27 includes the subject matter of any of Examples 21-26, and wherein the semiconductor die is a processor die.

Example 28 includes the subject matter of any of Examples 21-27, and wherein the semiconductor die is a memory die.

Example 29 includes the subject matter of any of Examples 21-28, and wherein the glass substrate comprises means for a second glass-core inductor with an inductance density greater than 20 nanohenries per square millimeter.

Example 30 includes a method comprising forming an inductor on a glass substrate, wherein forming the inductor on the glass substrate comprises forming a plurality of angled through-glass vias using laser-induced deep etching, wherein individual angled through-glass vias of the plurality of angled through-glass vias extend from a top surface of the glass substrate to a bottom surface of the glass substrate; and patterning a plurality of traces on the top surface of the glass substrate, wherein individual traces of the plurality of traces extend from one of the plurality of angled through-glass vias to another of the plurality of angled through-glass vias.

Example 31 includes the subject matter of Example 30, and wherein forming a plurality of angled through-glass vias using laser-induced deep etching comprises exposing the glass substrate to a laser to form a plurality of angled exposed regions defined in the glass substrate; etching the plurality of angled exposed regions to form the plurality of angled through-glass vias; and filling the plurality of angled through-glass vias with a conductive material that comprises copper.

Example 32 includes the subject matter of any of Examples 30 and 31, and wherein exposing the glass substrate comprises positioning a prism on the glass substrate to deflect a laser incident on the prism from normal to the top surface of the glass substrate.

Example 33 includes the subject matter of any of Examples 30-32, and further including integrating the glass substrate into an integrated circuit component, wherein the integrated circuit component comprises a fully-integrated voltage regulator (FIVR), wherein the FIVR comprises the inductor.

Example 34 includes the subject matter of any of Examples 30-33, and wherein the plurality of angled through-glass vias have a pitch between 80 and 300 micrometers.

Example 35 includes the subject matter of any of Examples 30-34, and wherein the inductor has inductance density greater than 20 nanohenries per square millimeter.

Example 36 includes the subject matter of any of Examples 30-35, and wherein the inductor has inductance greater than one nanohenry.

Example 37 includes the subject matter of any of Examples 30-36, and further including patterning a plurality of pads on the bottom surface of the glass substrate, wherein individual pads of the plurality of pads connect two of the angled through-glass vias of the plurality of angled through-glass vias.

Example 38 includes the subject matter of any of Examples 30-37, and further including forming a first plurality of build-up layers adjacent the top surface of the glass substrate; forming a second plurality of build-up layers adjacent the bottom surface of the glass substrate; and positioning a semiconductor die adjacent the first plurality of build-up layers.

Example 39 includes the subject matter of any of Examples 30-38, and wherein the semiconductor die is a processor die.

Example 40 includes the subject matter of any of Examples 30-39, and wherein the semiconductor die is a memory die.

Example 41 includes the subject matter of any of Examples 30-40, and further including forming a second inductor on the glass substrate, wherein forming the second inductor on the glass substrate comprises forming a second plurality of angled through-glass vias using laser-induced deep etching, wherein individual angled through-glass vias of the second plurality of angled through-glass vias extend from the top surface of the glass substrate to the bottom surface of the glass substrate; and patterning a second plurality of traces on the top surface of the glass substrate, wherein individual traces of the plurality of traces extend from one of the second plurality of angled through-glass vias to another of the second plurality of angled through-glass vias.

1. An apparatus comprising:
a glass substrate comprising an inductor, the inductor comprising:
a plurality of angled through-glass vias, wherein individual angled through-glass vias of the plurality of angled through-glass vias extend from a top surface of the glass substrate to a bottom surface of the glass substrate; and
a plurality of traces on the top surface of the glass substrate, wherein individual traces of the plurality of traces extend from one of the plurality of angled through-glass vias to another of the plurality of angled through-glass vias.

2. The apparatus of claim 1, wherein the apparatus comprises an integrated circuit component, wherein the integrated circuit component comprises the glass substrate, wherein the integrated circuit component comprises a fully-integrated voltage regulator (FIVR), wherein the FIVR comprises the inductor.

3. The apparatus of claim 1, wherein the plurality of angled through-glass vias have a pitch between 80 and 300 micrometers.

4. The apparatus of claim 1, wherein the inductor has inductance density greater than 20 nanohenries per square millimeter.

5. The apparatus of claim 4, wherein the inductor has inductance greater than one nanohenry.

6. The apparatus of claim 1, further comprising a plurality of pads on the bottom surface of the glass substrate, wherein individual pads of the plurality of pads connect two of the angled through-glass vias of the plurality of angled through-glass vias.

7. The apparatus of claim 1, further comprising:
a first plurality of build-up layers adjacent the top surface of the glass substrate;
a second plurality of build-up layers adjacent the bottom surface of the glass substrate; and
a semiconductor die adjacent the first plurality of build-up layers.

8. The apparatus of claim 7, wherein the semiconductor die is a processor die.

9. The apparatus of claim 7, wherein the semiconductor die is a memory die.

10. The apparatus of claim 1, wherein the glass substrate comprises a second inductor, the second inductor comprising:
a second plurality of angled through-glass vias, wherein individual angled through-glass vias of the second plurality of angled through-glass vias extend from the top surface of the glass substrate to the bottom surface of the glass substrate; and
a second plurality of traces on the top surface of the glass substrate, wherein individual traces of the second plurality of traces extend from one of the second plurality of angled through-glass vias to another of the second plurality of angled through-glass vias.

11. An apparatus comprising:
a glass substrate comprising an inductor, the inductor comprising a plurality of inductor turns, wherein individual inductor turns of the plurality of inductor turns comprise:
a first conductor extending from a top surface of the glass substrate to a bottom surface of the glass substrate, wherein the first conductor is angled at least ten degrees relative to a line normal to the top surface of the glass substrate;
a second conductor extending from the top surface of the glass substrate to the bottom surface of the glass substrate, wherein the second conductor is angled at least ten degrees relative to the line normal to the top surface of the glass substrate, wherein the second conductor is electrically coupled to the first conductor; and
a third conductor extending along the top surface of the glass substrate, wherein the third conductor is electrically coupled to the second conductor and an adjacent inductor turn of the inductor.

12. The apparatus of claim 11, wherein the apparatus comprises an integrated circuit component, wherein the integrated circuit component comprises the glass substrate, wherein the integrated circuit component comprises a fully-integrated voltage regulator (FIVR), wherein the FIVR comprises the inductor.

13. The apparatus of claim 11, wherein a distance between the first conductor and the second conductor of individual inductor turns of the plurality of inductor turns at the top surface is between 80 and 300 micrometers.

14. The apparatus of claim 11, wherein the inductor has inductance density greater than 20 nanohenries per square millimeter.

15. The apparatus of claim 14, wherein the inductor has inductance greater than one nanohenry.

16. The apparatus of claim 11, further comprising a plurality of pads on the bottom surface of the glass substrate, wherein individual pads of the plurality of pads connect the first conductor to the second conductor of individual inductor turns of the plurality of inductor turns.

17. The apparatus of claim 11, further comprising:
a first plurality of build-up layers adjacent the top surface of the glass substrate;
a second plurality of build-up layers adjacent the bottom surface of the glass substrate; and
a semiconductor die adjacent the first plurality of build-up layers.

18. The apparatus of claim 17, wherein the semiconductor die is a processor die.

19. An apparatus comprising:
a glass substrate comprising means for a glass-core inductor with an inductance density greater than 20 nanohenries per square millimeter;
a first plurality of build-up layers adjacent a top surface of the glass substrate; and
a second plurality of build-up layers adjacent a bottom surface of the glass substrate.

20. The apparatus of claim 19, wherein the apparatus comprises an integrated circuit component, wherein the integrated circuit component comprises the glass substrate, wherein the integrated circuit component comprises a fully-integrated voltage regulator (FIVR), wherein the FIVR comprises the glass-core inductor.

21. The apparatus of claim 19, wherein the glass-core inductor has inductance density greater than 20 nanohenries per square millimeter.

22. The apparatus of claim 21, wherein the glass-core inductor has inductance greater than one nanohenry.

23. A method comprising:
forming an inductor on a glass substrate, wherein forming the inductor on the glass substrate comprises:
forming a plurality of angled through-glass vias using laser-induced deep etching, wherein individual angled through-glass vias of the plurality of angled through-glass vias extend from a top surface of the glass substrate to a bottom surface of the glass substrate; and
patterning a plurality of traces on the top surface of the glass substrate, wherein individual traces of the plurality of traces extend from one of the plurality of angled through-glass vias to another of the plurality of angled through-glass vias.

24. The method of claim 23, wherein forming a plurality of angled through-glass vias using laser-induced deep etching comprises:
exposing the glass substrate to a laser to form a plurality of angled exposed regions defined in the glass substrate;
etching the plurality of angled exposed regions to form the plurality of angled through-glass vias; and
filling the plurality of angled through-glass vias with a conductive material that comprises copper.

25. The method of claim 24, wherein exposing the glass substrate comprises positioning a prism on the glass substrate to deflect a laser incident on the prism from normal to the top surface of the glass substrate.
